(19) United States
(12) Patent Application Publication
(10) Pub. No.: US 2012/0085387 A1
(43) Pub. Date: Apr. 12, 2012

(54) TRUCK MOUNTED SOLAR PANEL SYSTEM

(75) Inventor: William L. French, SR., Lexington, MA (US)

(73) Assignee: French Development Enterprises, N. Billerica, MA (US)

(21) Appl. No.: 13/228,022

(22) Filed: Sep. 8, 2011

Related U.S. Application Data
(63) Continuation of application No. 13/092,870, filed on Apr. 22, 2011, now abandoned.
(60) Provisional application No. 61/477,345, filed on Apr. 20, 2011.
(60) Provisional application No. 61/327,468, filed on Apr. 23, 2010.

(51) Int. Cl. H01L 31/045; F03D 9/00; H01L 31/052

(52) U.S. Cl. 136/245; 136/246; 290/55

(57) ABSTRACT

Solar power and other renewable energy systems are useful for generating electrical energy with no environmental effects. Example embodiments of the present invention provide for mobile transport of power generation systems, such as a solar power energy collection system, that can be transported via a mobile system, such as a truck, trailer, or railway transport system, and positioned anywhere the mobile transport system can travel to provide temporary or permanent energy producing capacity.

### RELATED APPLICATIONS

This application is a Continuation of application Ser. No. 13/092,870, filed on Apr. 22, 2011, which claims the benefit of U.S. Provisional Application No. 61/477,345, filed on Apr. 20, 2011, entitled “Truck Mounted Solar Panel System” by William L. French Sr., and claims the benefit of U.S. Provisional Application No. 61/327,468, entitled “Truck Mounted Solar Panel System” by William L. French Sr., filed on Apr. 23, 2010. The entire teachings of the above applications are incorporated herein by reference.

### BACKGROUND OF THE INVENTION

Solar power systems are useful for converting solar energy into useful electric energy. Solar panels have been used in many applications, such as residential or standalone systems, to provide energy needed to operate systems, such as emergency phone systems on highways or dishwashers and televisions in residences. Multiple solar power generation systems can be deployed to form solar power farms to provide electrical power to grids that are used to distribute energy to entire communities. Other forms of renewable energy systems are also useful in this regard.

### SUMMARY OF THE INVENTION

A mobile solar power system according to an embodiment of the present invention includes a mobile transport system and a solar panel power generation system configured to be transported by the mobile transport system in a retracted state and convert solar power in an operational state. Alternative example embodiments of the present invention include a method of transporting a solar power system, including maintaining a mobile transport system configured to carry a solar power system and configuring the solar power system to be transported by the mobile transport system in a retracted state and convert solar power in an operational state. Further example embodiments of the present invention include a mobile solar power system including a means for maintaining a mobile transport system configured to carry a solar power system and a means for configuring the solar power system to be transported by the mobile transport system in a retracted state and convert solar power in an operational state.

It should be understood that alternative embodiments may include other energy collection components, such as wind turbines, rather than solar collectors.

### BRIEF DESCRIPTION OF THE DRAWINGS

The foregoing will be apparent from the following more particular description of example embodiments of the invention and as illustrated in the accompanying figures. The drawings are not necessarily to scale, emphasis instead being placed upon illustrating example embodiments of the present invention.

The accompanying figures, where like reference numerals refer to identical or functionally similar elements throughout the separate views and which together with the detailed description below are incorporated in and form part of the Specification, serve to illustrate various embodiments further and to explain various principles and advantages all in accordance with example embodiments of the present invention. The teachings of all patents, published applications and references cited herein are incorporated by reference in their entireties.

FIG. 1A is a side view of a truck equipped with a solar panel assembly in a folded and retracted position.

FIG. 1B is a side view of the truck with solar panel assembly unfolded and raised to an operating state.

FIG. 2 is a rear view of the truck with extended outrigger support.

FIG. 3 is a rear view of the truck in a travel mode with a tri-fold solar panel assembly in which travel locking bars interconnect the raised solar panel elements to provide structural stability between them.

FIG. 4 is a rear view of a truck with a dual piston system configured to raise the solar panels and rotate the solar panels by way of a drive motor connected to a platform or other structural assembly to which the dual pistons are mounted.

FIG. 5 is a side view of the dual axis solar tracking system arranged in a travel mode.

FIG. 6 is a bottom view of a trailer with outriggers and tracker turntable.

FIG. 7 is a top view of a collection of truck or trailer mounted solar panels arranged to collect massive amounts of solar power.

FIG. 8 is a flow diagram of an embodiment of the present invention that illustrates a method of transporting a dual axis solar tracker.

### DETAILED DESCRIPTION OF THE DRAWINGS

A description of example embodiments of the invention follows. An example embodiment of the present invention includes a truck equipped with foldable solar panel assemblies that can be transported and deployed in a simple and effective manner. The solar panel assemblies may be foldable in any number of ways to fold and retract the solar panels when not in use. For example, the solar panels can be folded along a single axis or multiple parallel or nonparallel axes.

A lift system, such as hydraulic, pneumatic, electromechanical, or fully mechanical piston system, can be configured to raise a folded or unfolded assembly of the solar panel assemblies above the chassis of the truck and, optionally, rotate the solar panel assemblies to be directed at the source of solar energy, typically the sun, or be configured to track the position of the sun, or other energy source, automatically. Alternatively, the solar panel assemblies may be interspersed or otherwise assembled with mirror assembly components such that the solar panels can collect energy from the sun directly or via reflection of sunlight by the mirrors onto the solar panels. In such an embodiment, the structure associated with the piston system, which may be a single or multi-piston system, may be configured to support the mirror and solar panel assembly in a uniform or distributed manner.

The truck or trailer may have a stabilizing system with extendable arms to enhance its stability during periods where the solar panels are raised, and the stabilizing system may also provide weight bearing capability to offset weight from the truck or trailer. The system enables the shape and number of solar panels to be scalable in technology, power production, size, and other features or parameters associated with solar panels. For example, the piston system can rotate at individual piston segments or have a base that rotates the entire piston system such that a multi-piston system can be rotated about a central axis to enable rotation of the solar panels.

The truck or trailer (i.e., mobile transport system) may include an assembly having an inverter to convert the collected and converted solar power into energy that can be stored in batteries or directly transmitted along cabling to systems that use the energy locally or distribute the energy, such as via a power grid, to systems that use the energy remotely.

The solar panel system may have auxiliary power cells that are positioned at a portion of the solar panel assembly (e.g., on a rear face of a solar panel that is facing upward in a folded configuration of the solar panel system) or structure supporting same such that the auxiliary power cells themselves collect and provide power to the piston system to enable the piston system to unfold and raise a solar collector frame having the bulk of the solar panel cells. It should be understood that the hydraulics provided by the truck can also be employed, and, further, energy provided by the truck, including power generated by the truck's engine, can be employed to provide power to enable the piston system to unfold and raise the solar collection panels.

An energy storage system, such as a battery storage system, can further be provided on a utility trailer such that a megawatt or more of energy can be stored from either a single truck assembly or from multiple truck assemblies collected in a single or multiple area(s).

The construction of the trailer or truck may include features to transport the retracted and folded solar collection assembly along bumpy roads or up and down steep inclines. It should also be understood that the truck may employ any amount of dampening, such as air bearings, to transport the solar panel system safely from site to site.

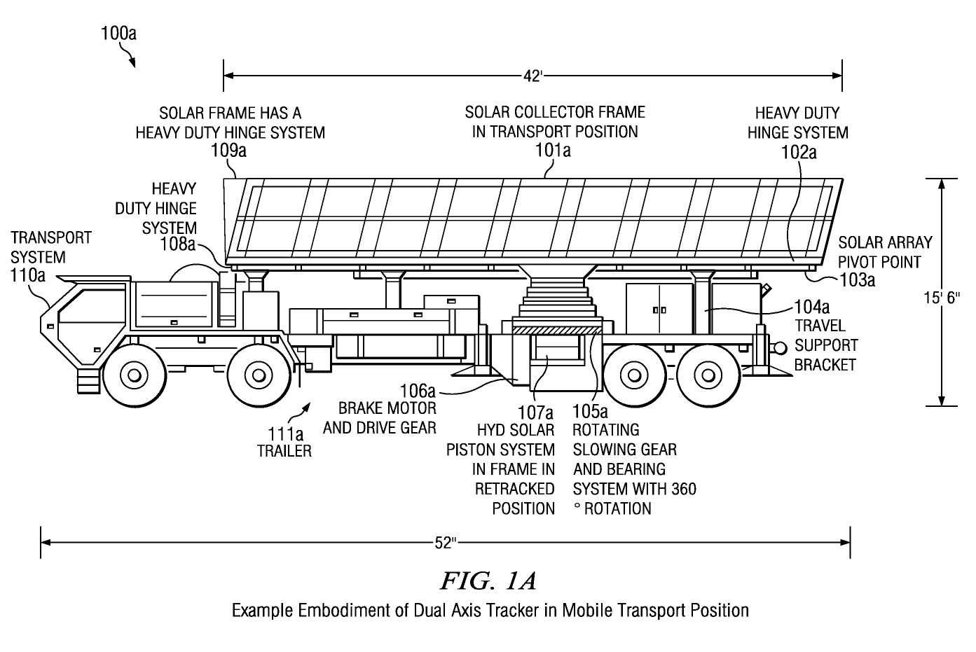

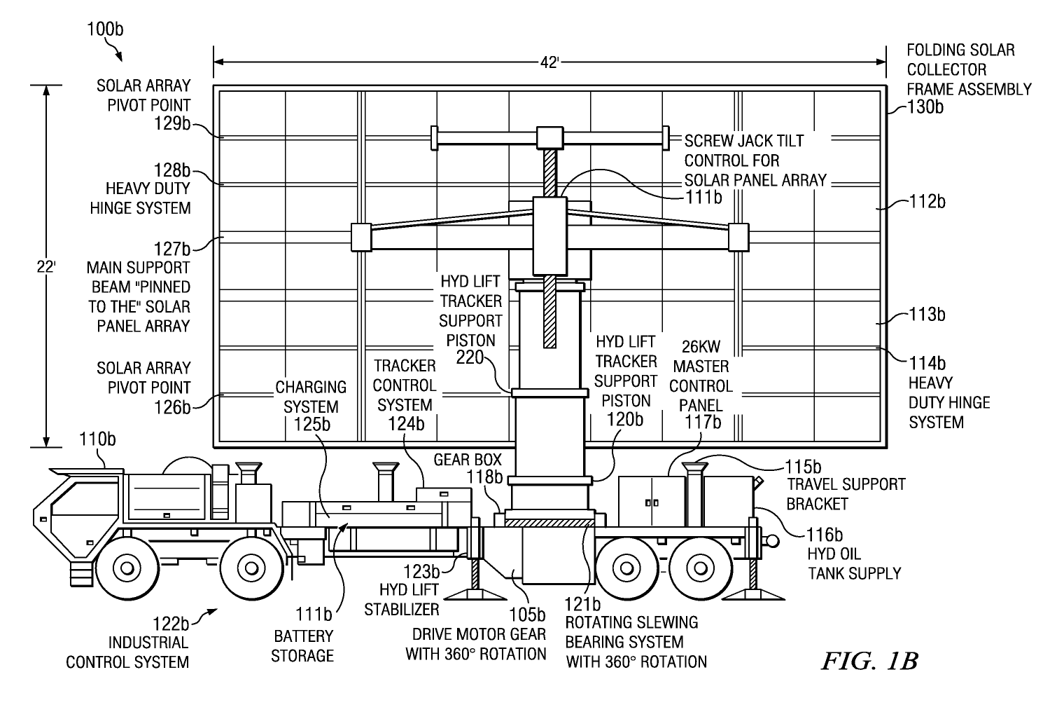

FIG. 1A is a diagram 100a of a side view of a mobile transport system, for example a truck 110a with trailer having a foldable solar collector frame 101a in a transport position with solar panels to collect solar energy and convert the solar energy into useful electrical energy. The frame in the embodiment of FIG. 1A is folded along a single axis such that the solar panels face each other during transport. The solar panels may be connected together at the top portion away from the trailer to connect the solar panels together for structural stability during transport. The folding occurs at a hinge assembly 102a that is heavy duty to provide sufficient structural support for the solar panels and also provides a sufficient amount of rotation to open the solar panels to a near flat, flat, concave or convex position.

The trailer may further include a rotating slewing gear assembly optionally with an air bearing system 105a to provide 360° of rotation of the solar panel collectors to enable tracking the sun in any orientation of the truck or trailer. Further, the trailer includes a pistoning system 107a, which may be hydraulic, pneumatic, or electro-mechanical. The pistoning system 107a may be telescoping in that there may be multiple segments of the pistoning system or just a single segment of the pistoning system. Further, the truck 110a may include a travel support bracket 104a or multiple travel support brackets to offload some of the weight of the solar panels from the pistoning system fore and aft of the pistoning system, and possibly laterally, depending on the travel configuration of the solar paneling during transport. Further, the pistoning system may be mounted to an assembly including a drive motor and drive gear 106a to enable rotating the solar panels in a refracted or operational configuration.

FIG. 1B is a diagram 100b of a side view of a mobile transport system, such as a truck 110b, with trailer 111b and solar collector frame assembly 130b in an unfolded state. The solar panel may allow for dual axis solar tracking and include battery storage 125b on the trailer or other mobile transport for tactical deployment. The solar panel array 129b may have a pivot point 126b and heavy-duty hinge system 128b with a main support being pinned to the solar panel array. The solar panel array may be foldable in one or multiple axes while transforming from the retracted travel configuration to the unfolded operational configuration. Further, the dimensions of the array may be, for example purposes only, 32 feet by 42 feet, but may be larger or smaller depending on the application, mobile transport size, and other factors, such as power requirements and expected transport pathways, such as used in an urban or rural environment. Further, the assembly may include a tracker control system 124b that is electrically coupled to the drive motor system 105b and optionally connected to a gear box 118b, rotating slewing bearing system 121b, inverter control panel 117b, and other known or useful controls systems and components to control rotation of the drive motor system to steer the antenna anywhere in the direction of the sun or other source, including, for example, a mirror (not shown) reflecting the sun.

It should be understood that the solar panel array may be mounted to a frame made of any materials, which may be any metal or nonmetal, and may have stiffness properties such that individual panels do not bend beyond their accepted tolerances. Examples of materials include aluminum and stainless steel, titanium, graphite or other composite and other materials known in the art for providing structural stability to thin materials covering large surface areas, such as the solar panels in the present example.

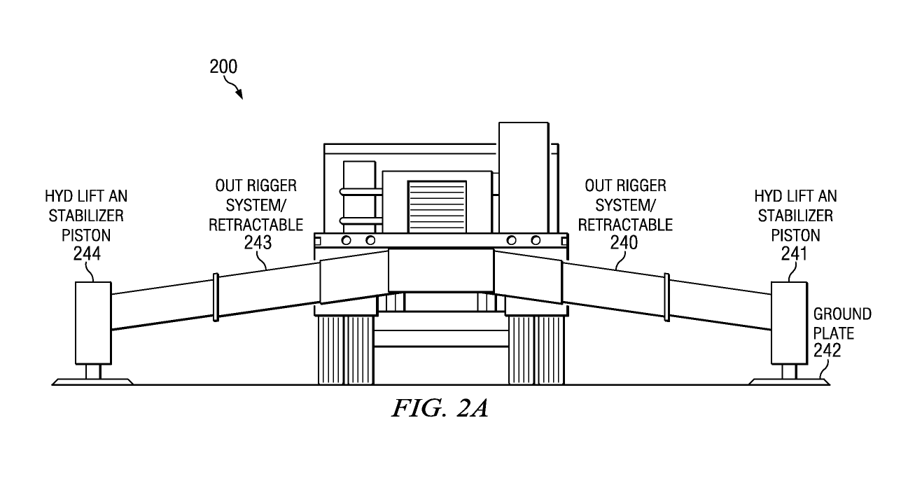

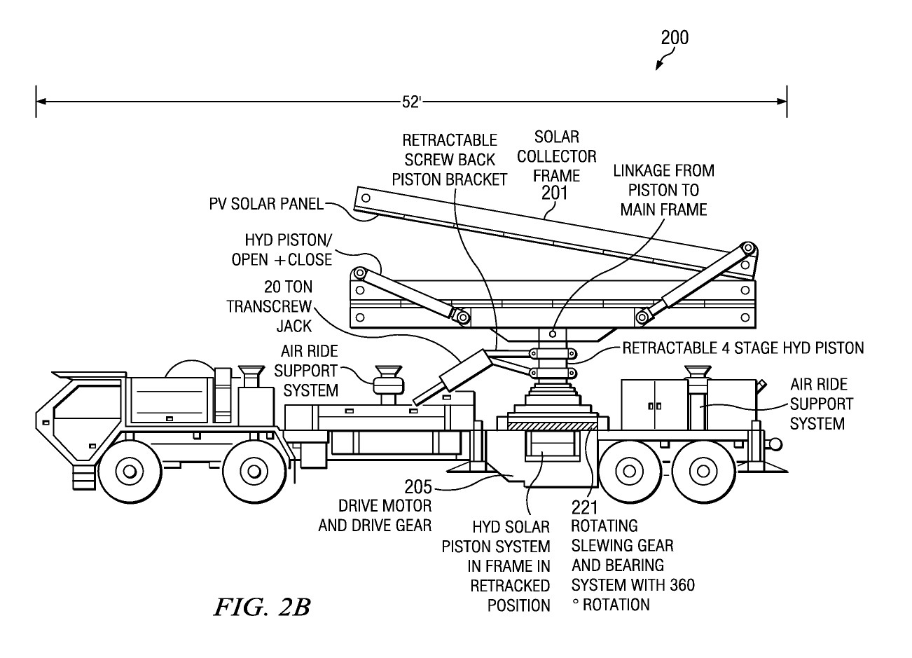

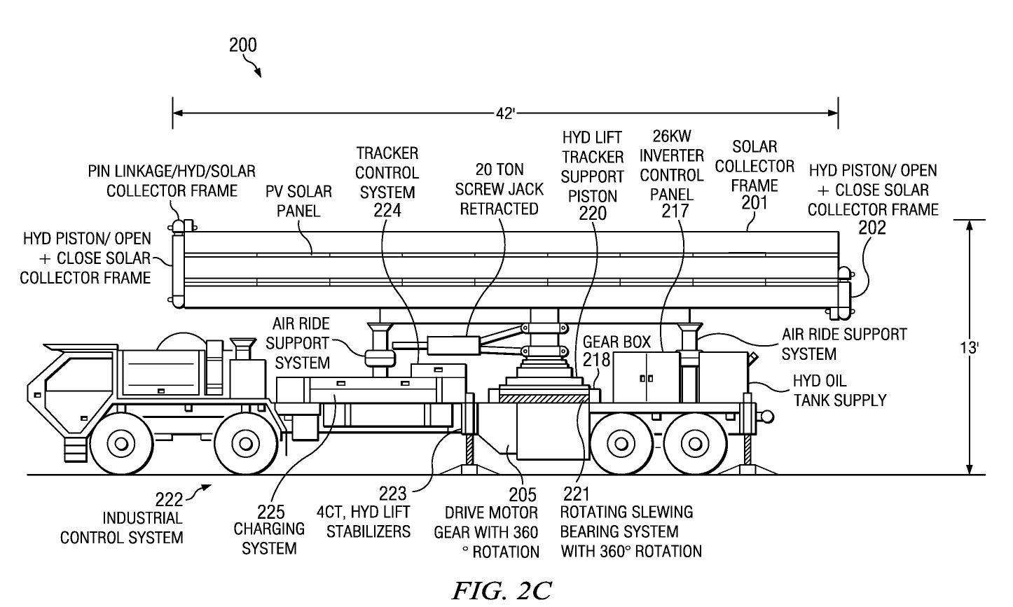

FIG. 2 is a diagram 200 of multiple views of the solar mobile transport system in which outriggers 240 and 243 that are retractable and may include hydraulic lifts 241 and 244 at the end of the pistons to provide structural support and balance for the mobile transportation system. The outriggers can be of any length desired or required to provide the level of support and, optionally, weight bearing, required.

In some example embodiments of the diagram 200, before a solar tracker system is deployed from a traveling state to an operational state in the mobile transport system, all stabilizers must be deployed to balance the mobile system. Further stabilizers may include a ground plate 242 or other such forms of stabilization as is currently known or hereinafter developed as may be useful for a mobile transport system and trailer mounted with a fixed tracking solar panel.

Alternative example embodiments of the solar collector folding into a retracted position, such as the solar collector of FIG. 1B and another alternative embodiment of the solar collector folded in a ready state to be deployed or re-deployed to the operational position. These alternative example embodiments may include similar features as the mobile transport device as in FIG. 1B, such as drive motors and drive gears 205, hydraulic lift tracker support pistons 220, rotating slewing gear and bearing system 221, industrial control system with intelligent management software 222, a tracker control system 224, a battery storage system 225, and any additional or combination of systems and components as may be useful in the transport of a solar system, such as the dual axis solar tracking system of FIG. 1A.

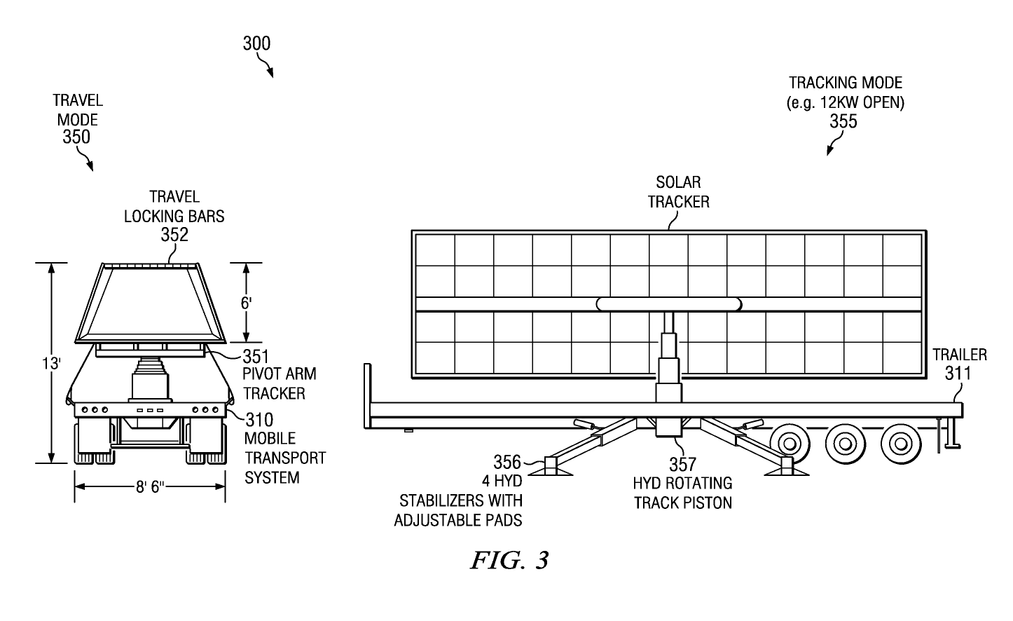

FIG. 3 is a diagram 300 that illustrates a rear view of the mobile transport system 310 and trailer 311 using a solar panel array having two axes of rotation: one axis on a left edge of a horizontal solar panel and another axis on a right edge of the horizontal solar panel. The axes of rotation support rotation of two other solar panels extended from the horizontal solar panel, where, in a transport or travel mode 350, the other solar panels are rotated upward, optionally at concave or convex angles relative to the horizontally positioned solar panel. Travel-locking bars 352 may be configured to be coupled to the raised solar panels at an upper end of the raised solar panels such that structural stiffness is provided between the raised solar panels to provide for travel on the mobile transport. Hydraulic stabilizers 356, optionally with adjustable pads, may be employed to provide support for a dual axis solar tracker deployed in a tracking mode 355. Further example embodiments of the diagram 300 may include hydraulic rotating track pistons 357, or other type of piston as is known in the art or hereinafter developed, for use during tracking mode.

Example dimensions of the diagram 300 may include 8′6″ of mobile transport with an 8′6″ of horizontally positioned solar panel plus rotation assembly for the rotating portions of the solar paneling. The height of the overall transport system, including the solar panels in a travel mode, may be as high as 13 feet, where the height of the raised solar panels may be 6 feet of those 13 feet. It should be understood that the dimensions just provided are example dimensions only, but these dimensions are provided to support transport beneath most bridges found in the United States, at least on major interstate highways.

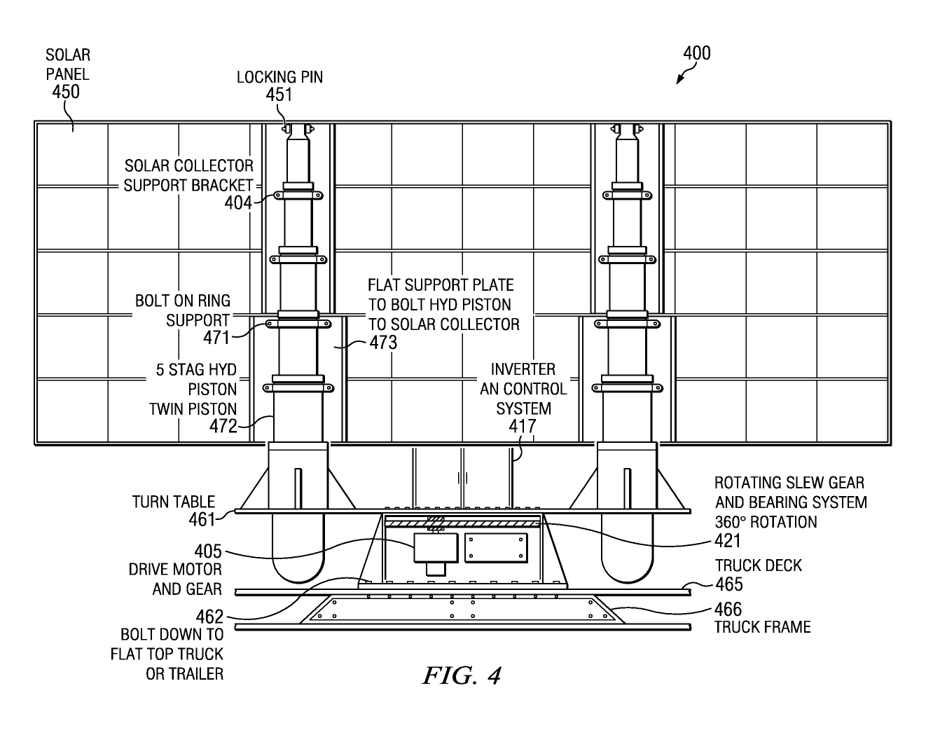

FIG. 4 is a diagram 400 that illustrates a rear view of the solar panels 450 in an unfolded position, or a folded position, depending on length of the piston assembly. In FIG. 4, there are two pistons 472 within the piston assembly that are connected to a turntable 461 that is driven by a drive motor and gear 405. The pistons 472 may be bolted with the solar collector 404 via a flat support plat 473 or other bolt, bracket, or linkage system. The turntable 461 can be bolted to a flat top truck 462 or trailer and rotate, optionally using a slewing gear drive and bearing system 421, which can turn 360° in rotation in some embodiments.

The pistons may be telescoping pistons having multiple segments thereof with a locking pin 451 that is configured to maintain an open (or folded and refracted) position of the solar panels 450. An inverter and control system 417 may be provided on the turntable 461 or on the trailer, such as the truck deck 465 or the truck frame 466. In the case of having the inverter and control system 417 on the trailer, the turntable 461 may provide slip rings (not shown) to allow for electricity to be passed from the stationary surface to the rotating surface (and vice-versa) without electrical disruption and with full 360° rotation or beyond.

Alternatively, a non-slip ring embodiment may be employed through other forms of communications links, including wire harnesses, which can transport electricity from a rotating turntable 461 to a stationary mount. Further, battery storage (not shown) may be provided on the stationary platform, such as the truck's deck 465 or truck frame 466, and have cable harnesses or other means of electrical transport (not shown), to provide transport of electrons converted from photons by the solar panels to the energy storage devices, such as batteries.

It should be understood that a trailer or other support structure used for the mobile transport of the entire solar panel collection system is to have sufficient structural integrity for stationary and moving transport of the solar panel array assembly. Thus, large I-beams may further be employed if a normal chassis of a truck or trailer is insufficient to carry the weight of the solar panel assembly. Further, any form of vibration or shock reduction can be employed, such as air bearings or other cushioning devices, to allow mobile transport on uneven or highly bumpy surfaces, such as roads that are affected by freezing and thawing effects in northern climates.

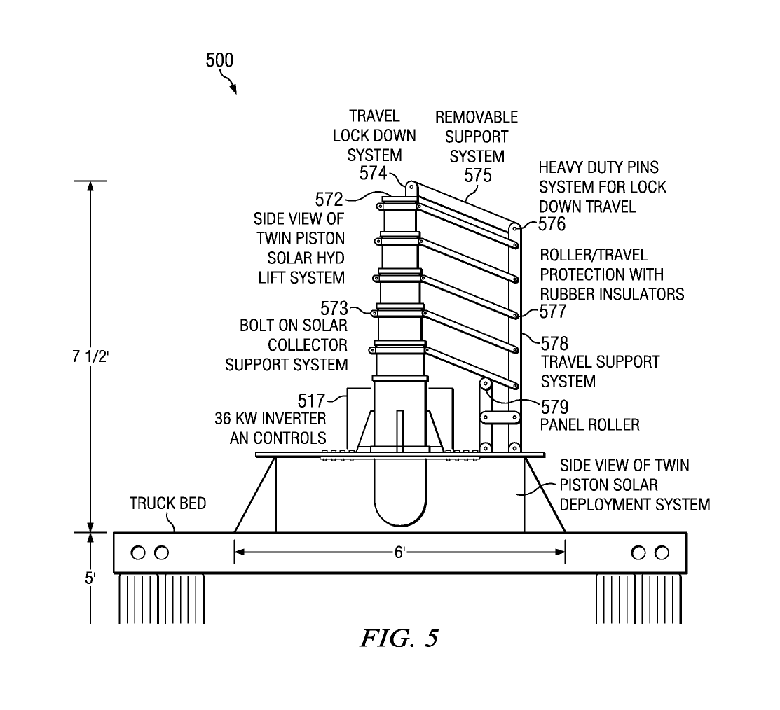

FIG. 5 is a diagram 500 of a side view of a dual axis solar tracking system in a travel mode. The twin piston solar hydraulic lift system 572 may be collapsed downward on itself in a partially or fully retracted position, and a travel lockdown system 574 may be employed with a removable support system 575. Heavy-duty pins 576 may be included to provide for lockdown travel, including having roller/travel protection with rubber insulators 577 or the like. A panel roller 579 may be provided such that additional structural integrity is provided for the solar panels in a retracted position.

Further, continuing to refer to the example embodiments of FIG. 5, the solar panel assembly may itself be a bolt-on solar collector support system 573 such that any size or configuration of solar panels can be removably coupled to the pistoning system(s). Examples of such bolt-on solar collector support systems are simple metal straps with bolts at an open end of a U or circular shape such that flanges extending in parallel with each other can be interconnected with sufficient force to couple the bolt on support system properly to the piston and maintain such support during transport and operational deployment, including during periods of motion where the piston travels from non-extended to extended positions.

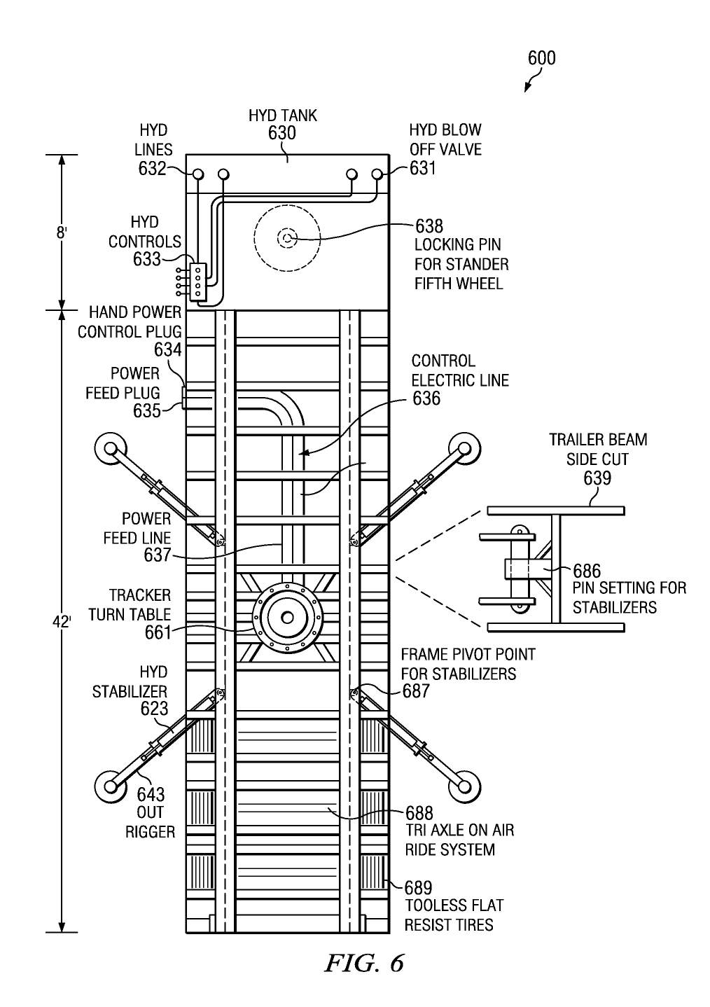

FIG. 6 is a diagram 600 of an example embodiment of a bottom view of the transport system, such as a truck, trailer, railcar, or other transport system, that illustrates outriggers 643 that are coupled thereto to provide lateral and/or weight bearing support. The outriggers 643 may be coupled to or operated with a power feed plug 635, or in cases requiring manual operation, a hand powered control plug 634 may be available. The outriggers 643 may be hydraulically stabilized via stabilizers 623 and/or stabilized via a frame pivot point 678. The bottom view of FIG. 6 illustrates hydraulic controls 633 that can be used to actuate the piston(s). In some embodiments of the present invention, the hydraulic controls 633 can be coupled to or be operable with a hydraulic tank 630 via hydraulic lines 632. The hydraulic tank 630 may be coupled with a hydraulic blow-off valve 631 for the release of gasses or pressure build up. Further, electrical control lines 636 may also be available to an operator of the solar panel assembly to operate angle of the solar panels or otherwise activate a control system to control angles of the solar panels automatically during operation or even to cause raising and lowering of the solar panels for operational or transport mode configurations.

The transport system may optionally include a tri-axel design on an air ride system 688 or other tires, such as tires 683, and further optionally include other forms of transport shock and vibration minimization systems for protection of the solar panel assembly.

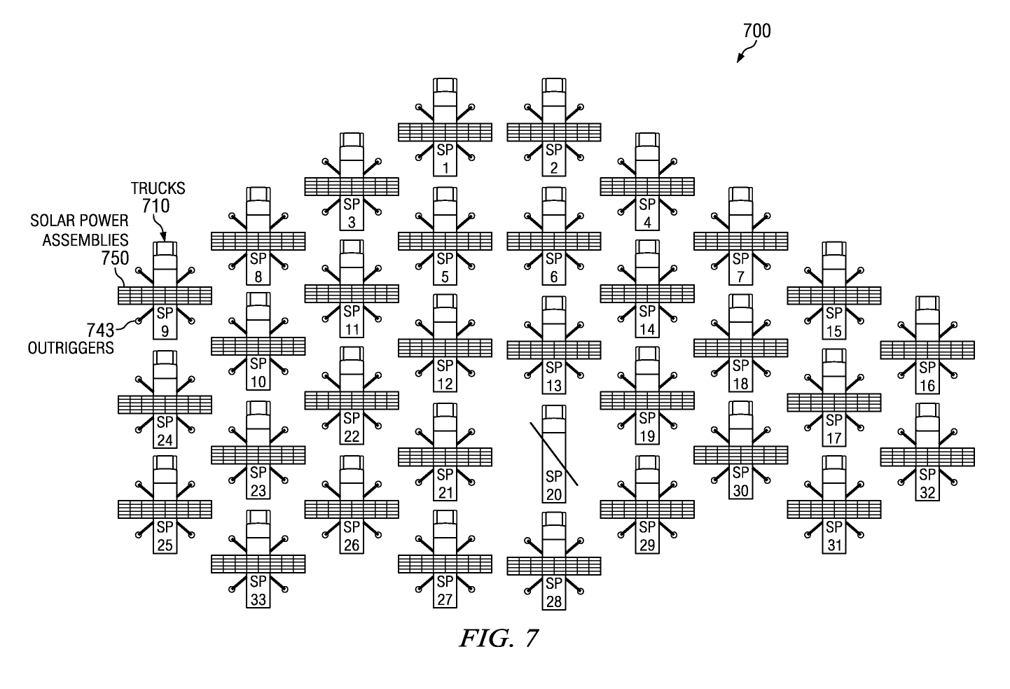

FIG. 7 is a diagram 700 of a top view of multiple solar panel assemblies 750 configured on trailers 711 or trucks 710 that are in operating states. Each of the trucks 710 is illustrated as having outriggers 743 to provide vertical or lateral support for the trucks since, in an operational state, the solar panel assemblies 750 are exposed to wind and other environmental factors that can produce excessive force on the assembly to cause the trucks or trailers to tip over. Although not shown, the energy converted and produced at each of the solar panel assemblies can be collected locally at each truck or, optionally, collected remotely at a central energy storage unit, such as one on a separate truck or at a central office. Further, multiple energy storage facilities can be provided and then collected energy can be delivered to a central facility. Still further, a coupling, such as a cable assembly, can be provided to provide direct or indirect transport of the energy to a power grid or provide energy directly to end users.

Alternative example embodiments of the present invention may be implemented on additional forms of mobile transport devices such as trains and boats, or, alternatively, on non-mobile locations that require the ease of use and storage of such a solar power system based on the location or configuration of the location, for example, on an oil rig at sea.

Further alternative examples of the present invention may be configured to raise a folded assembly of solar panels and configure the solar panels in such a way as to provide the solar collector arrays facing outward toward the sun but maintaining the solar panels in a retracted state while continuing to collect energy while in a folded and traveling state.

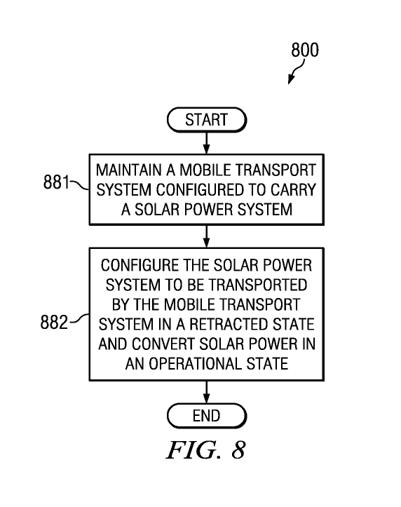

FIG. 8 is a flow chart 800 of an embodiment of the present invention that illustrates a method of transporting a dual axis solar tracker. After beginning, the method of flow chart 800 maintains a mobile transport system configured to carry a solar power system (881) and configures the solar power system to be transported by the mobile transport system in a retracted state and convert solar power in an operational state (882).

Further example embodiments of the present invention may include a non-transitory computer readable medium containing instruction that may be executed by a processor, and, when executed, causes the processor to perform different functions, for example, configure a dual axis solar tracker for transport. It should be understood that elements of the block and flow diagrams described herein may be implemented in software, hardware, firmware, or other similar implementation determined in the future. In addition, the elements of the block and flow diagrams described herein may be combined or divided in any manner in software, hardware, or firmware. If implemented in software, the software may be written in any language that may support the example embodiments disclosed herein. The software may be stored in any form of computer readable medium, such as random access memory (RAM), read only memory (ROM), compact disk read only memory (CD-ROM), and so forth. In operation, a general purpose or application specific processor loads and executes software in a manner well understood in the art. It should be understood further that the block and flow diagrams may include more or fewer elements, be arranged or oriented differently, or be represented differently. It should be understood that implementation may dictate the block, flow, and/or network diagrams and the number of block and flow diagrams illustrating the execution of embodiments of the invention.

While this invention has been particularly shown and described with references to example embodiments thereof, it will be understood by those skilled in the art that various changes in form and details may be made therein without departing from the scope of the invention encompassed by the appended claims.

What is claimed is:

1. A mobile power system, comprising:
a mobile transport system; and
a power generation system configured to be transported by the mobile transport system in a retracted state and convert energy to available power in an operational state.

2. The mobile power system of claim 1 wherein the power generation system is a solar power system or a wind turbine system.

3. The mobile power system of claim 1 wherein the power generation system includes power assemblies configured to be foldable along any axis.

4. The mobile power system of claim 1 further comprising a lift system configured to raise a folded or unfolded power generation assembly above a chassis of the mobile transport system.

5. The mobile power system of claim 3 wherein the lift system is further configured to rotate the panel assembly to be directed at the source of energy collection in a manner capable of tracking the position of the energy source.

6. The mobile power system of claim 1 wherein the power generation system is a solar power system assembled to operate with mirrored components in a manner enabling direct or indirect collection of energy.

7. The mobile power system of claim 1 wherein the mobile transport system further includes a stabilizing system, optionally including extendable arms, to enhance stability of the mobile transport system and the mobile solar power system.

8. The mobile power system of claim 1 wherein the mobile transport system further includes an energy assembly having an inverter to convert collected power into useable energy.

9. A method of transporting a power system, the method comprising:
maintaining a mobile transport system configured to carry a power generation system; and
configuring the power generation system to be transported by the mobile transport system in a retracted state and convert energy to available power in an operational state.

10. A mobile power system, comprising:
means for transporting a power generation system; and
means for configuring the power generation system to be transported by the mobile transport system in a retracted state and convert energy to available power in an operational state.
